(19) United States
(12) Patent Application Publication
(10) Pub. No.: US 2017/0074902 A1
(43) Pub. Date: Mar. 16, 2017

(54) CONTACT UNIT AND INSPECTION JIG

(71) Applicant: YOKOWO CO., LTD., Kita-ku (JP)

(72) Inventor: Takahiro NAGATA, Tomioka-shi (JP)

(73) Assignee: YOKOWO CO., LTD., Kita-ku (JP)

(21) Appl. No.: 15/264,746

(22) Filed: Sep. 14, 2016

(30) Foreign Application Priority Data
Sep. 15, 2015 (JP) 2015-182081

(51) Int. Cl. G01R 1/04

(52) U.S. Cl. CPC G01R 1/0441

(57) ABSTRACT

A contact unit which is to be detachably attached to a body of an inspection jig, includes: a flexible board which is provided with a contact part to be in contact with an object to be inspected, on one face thereof; a support member which is configured to support the flexible board; and a block which is provided on a side of the other face of the flexible board. A first ground pattern is provided on the one face of the flexible board, a signal pattern is provided on the other face of the flexible board, a through hole for electrically connecting the signal pattern to the contact part is formed in the flexible board, and the first ground pattern covers the signal pattern with the flexible board interposed between the first ground pattern and the signal pattern.

### CROSS-REFERENCE TO RELATED APPLICATION (S)

This application is based upon and claims the benefit of priority from prior Japanese patent application No. 2015-182081, filed on Sep. 15, 2015, the entire contents of which are incorporated herein by reference.

### BACKGROUND

The present invention relates to a contact unit and an inspection jig such as a probe card, which are used, for example, for inspecting electrical performance of a semiconductor integrated circuit.

An inspection jig such as a probe card which is used for inspecting electrical performance of semiconductor integrated circuit includes a flexible board which is provided with a contact part to be in contact with an electrode of an object to be inspected (a wafer, for example). A block for pressing the flexible board against the object to be inspected is provided on a back side of the contact part of the flexible board. The block is urged toward the object to be inspected by an urging unit such as a spring, and thus, a contact force with respect to the object to be inspected is applied to the flexible board.

On occasion of inspecting the electrical performance, electric signals at high frequency are transmitted between the inspection jig and an inspection apparatus (a tester) by way of a coaxial cable. The inspection jig is provided with a coaxial connector for enabling the coaxial cable which is extended from the tester to be detachably connected. The coaxial connector is electrically connected to the flexible board by soldering or so. Electrical connection between the contact part of the flexible board and the coaxial connector is performed by an electrically conductive pattern which is provided on the flexible board (see, for example, Japanese Patent No. 3942042 and Japanese Patent No. 4237761).

A number of devices (IC chips) which are divided later into individual pieces are formed in proximity with each other, on the wafer. The inspection of the wafer is carried out on every set of the devices of the predetermined number (single or plural). Therefore, in case where the object to be inspected is the wafer, a signal pattern which is provided on one face of the flexible board (the face at the wafer side) is opposed to the device which is adjacent to the device under inspection, in proximity with each other, and capacitive coupling or inductive coupling may occur. As the results, there has been such a problem that mismatch of impedance occurs, and inherent performance of the device cannot be measured with high accuracy.

### SUMMARY

It is an object of the invention to provide a contact unit and an inspection jig capable of measuring performance of a device with high accuracy.

In order to achieve the object, according to an aspect of the invention, there is provided a contact unit which is to be detachably attached to a body of an inspection jig, the contact unit comprising: a flexible board which is provided with a contact part to be in contact with an object to be inspected, on one face thereof; a support member which is configured to support the flexible board; and a block which is provided on a side of the other face of the flexible board, wherein a first ground pattern is provided on the one face of the flexible board, a signal pattern is provided on the other face of the flexible board, a through hole for electrically connecting the signal pattern to the contact part is formed in the flexible board, and the first ground pattern covers the signal pattern with the flexible board interposed between the first ground pattern and the signal pattern.

According to an aspect of the invention, there is also provided an inspection jig comprising: a flexible board which is provided with a contact part to be in contact with an object to be inspected, on one face thereof; a support member which is configured to support the flexible board; and a block which is provided on a side of the other face of the flexible board, wherein a first ground pattern is provided on the one face of the flexible board, a signal pattern is provided on the other face of the flexible board, a through hole for electrically connecting the signal pattern to the contact part is formed in the flexible board, and the first ground pattern covers the signal pattern with the flexible board interposed between the first ground pattern and the signal pattern.

### BRIEF DESCRIPTION OF THE DRAWINGS

FIG. 1 is an exploded perspective view of a contact unit 30 in Embodiment 1 according to the invention, as seen from the below.

FIG. 2 is an exploded perspective view of the contact unit 30, as seen from the above.

FIG. 3 is an exploded perspective view of an inspection jig 1 in Embodiment 1 according to the invention, as seen from the below.

FIG. 4 is an exploded perspective view of the inspection jig 1, as seen from the above.

FIG. 5 is a perspective view of the inspection jig 1 in which a unit pressing member 90 is omitted, as seen from the below.

FIG. 6 is a perspective view of the inspection jig 1 in which the unit pressing member 90 is omitted, as seen from the above.

FIG. 7 is an enlarged sectional view of a region surrounding a mutual contact part between a flexible board 40 and a wafer 5 during inspection using the inspection jig 1.

FIG. 8 is an enlarged sectional view of a region surrounding a bump 41b for high-speed signals during the inspection using the inspection jig 1 (a block 70 and a bonding sheet 80 appearing in FIG. 7 are omitted).

FIG. 9 is a sectional view taken along a line A-A in FIG. 8, showing a case where the signals are transmitted by way of a micro strip line.

FIG. 10 is a sectional view taken along the line A-A in FIG. 8, showing a case where the signals are transmitted by way of a coplanar line.

FIG. 11 is an enlarged plan view of a region surrounding a center part of the flexible board 40 as seen from the block 70, in which the block 70 is imaginarily shown by a broken line.

FIG. 12 is an enlarged bottom view of a region surrounding the center part of the flexible board 40 as seen from the object to be inspected (the wafer 5), in which the block 70 is imaginarily shown by a broken line.

FIG. 13 is an enlarged sectional view of a region surrounding the bump 41b for high-speed signals during the inspection using an inspection jig, in a comparative example.

FIG. 14 is a sectional view taken along a line B-B in FIG. 13.

FIG. 15 is an enlarged sectional view of a part during the inspection using an inspection jig in Embodiment 2 according to the invention, in case where the signals are transmitted by way of a micro strip line (corresponding to FIG. 9).

FIG. 16 is a sectional view of the same in case where signals are transmitted by way of a coplanar line (corresponding to FIG. 10).

FIG. 17 is a bottom view of the bonding sheet 80 in FIG. 15 or 16.

FIG. 18 is an enlarged bottom view of a region surrounding a flat face part 74 of the block 70 in FIG. 15 or 16.

### DETAILED DESCRIPTION OF EXEMPLARY EMBODIMENTS

Now, referring to the drawings, preferred embodiments of the invention will be described in detail. It is to be noted that the same or equivalent constituent elements, members and so on which are shown in the respective drawings are denoted with the same reference numerals, and overlapped descriptions are appropriately omitted. Moreover, the embodiments do not limit the invention, but they are only examples, and all features and combinations of the features which are described in the embodiments are not absolutely essential to the invention.

### Embodiment 1

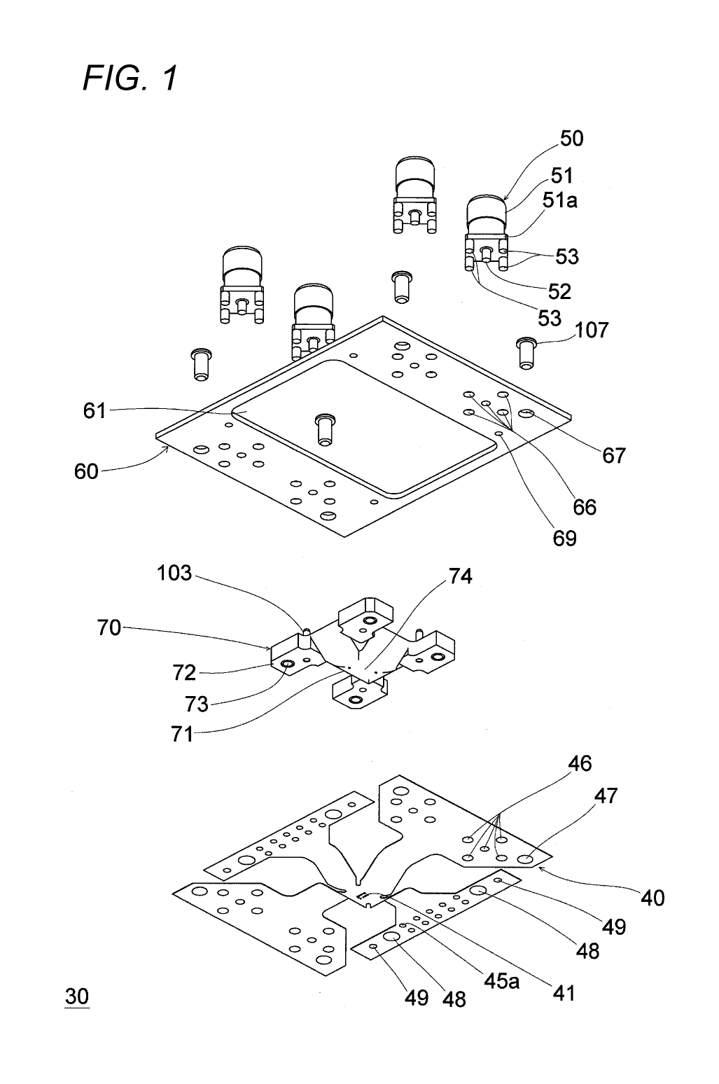

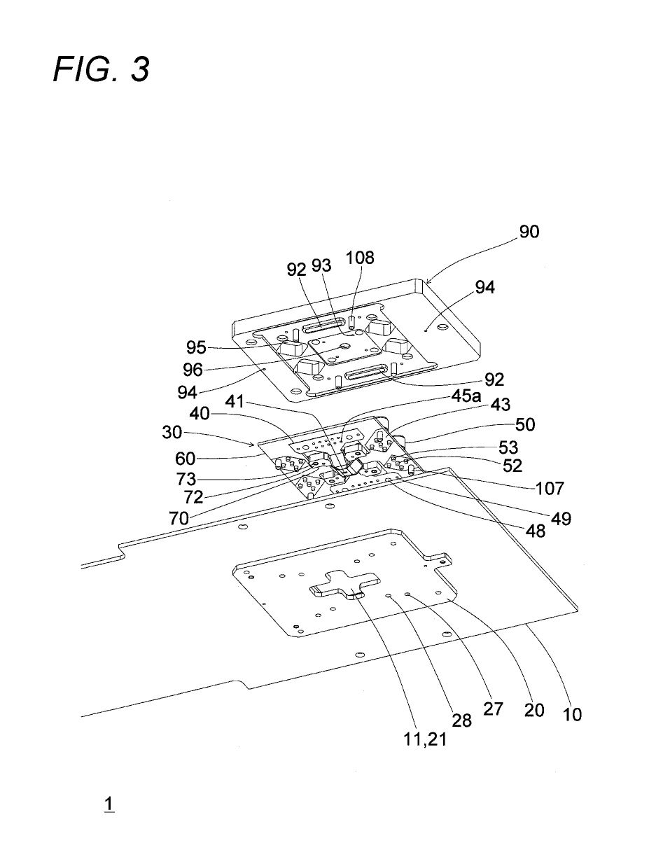

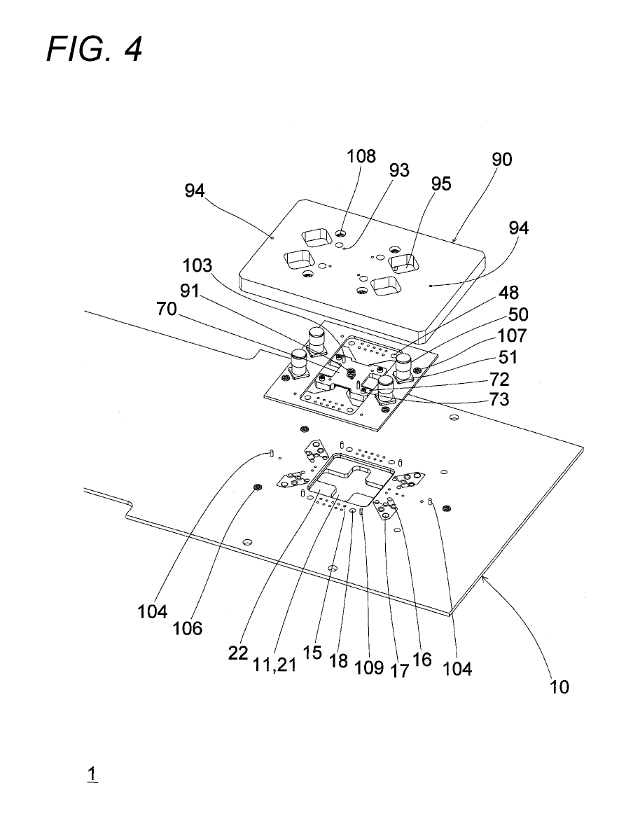

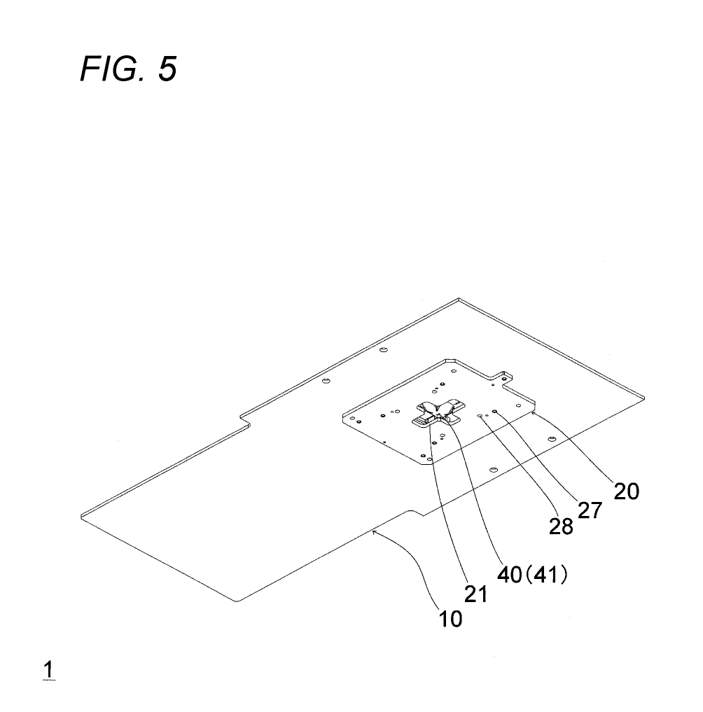

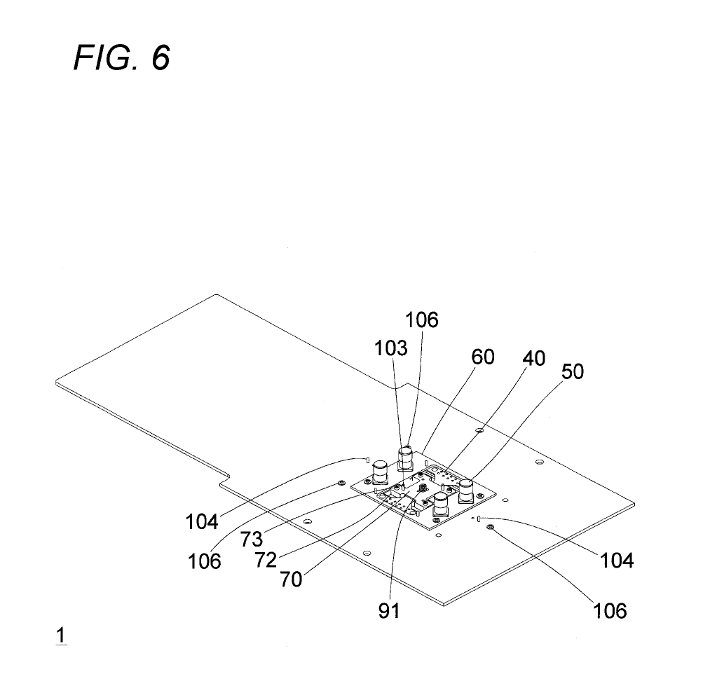

To begin with, structures of a contact unit 30 in this embodiment and an inspection jig 1 provided with the contact unit 30 will be described, referring to FIGS. 1 to 6. The contact unit 30 is an exchangeable contact unit for the inspection jig such as a probe card, and detachably fixed to a main board 10 of the inspection jig 1, as shown in FIGS. 3, 4 and so on. The contact unit 30 includes a flexible board 40, four pieces of coaxial connectors 50 such as an SMA connector, a sub board 60 formed of a hard board such as a glass epoxy board, and a block 70 formed of, for example, a resin molded body. The block 70 is provided for the purpose of bringing the flexible board 40 into contact with the object to be inspected. When the flexible board 40 is in contact with the object to be inspected, the block 70 reliably presses the flexible board 40 against the object to be inspected, and holds the flexible board 40 so as not to move. For this reason, the block 70 is preferably formed of hard material, and the material such as polyimide or polyimide-amide is most preferable.

The flexible board 40 is provided for coining into contact with the object to be inspected such as a wafer. The flexible board 40 is positioned on one face (a lower face) of the sub board 60. As shown in FIG. 1, a center part of a lower face (the face at an opposite side to the sub board 60) of a cross part of the flexible board 40 is defined as a contact region 41 to be in contact with the object to be inspected such as the wafer. Respective bumps (contact parts) which are in contact with an electrode of the object to be inspected during the inspection, specifically, bumps for high-speed signals, bumps for low-speed signals, bumps for power supply and bumps for grounding are provided in the contact region 41. Electrically conductive patterns for signal transmission and for power supply are led from the respective bumps except the bumps for grounding. The respective conductive patterns are extended to end parts of the cross part of the flexible board 40, and electrically connected to joint parts with respect to leg portions for signals of the coaxial connectors 50 or through holes 45a. The through holes 45a are provided for electrical connection with the main board 10.

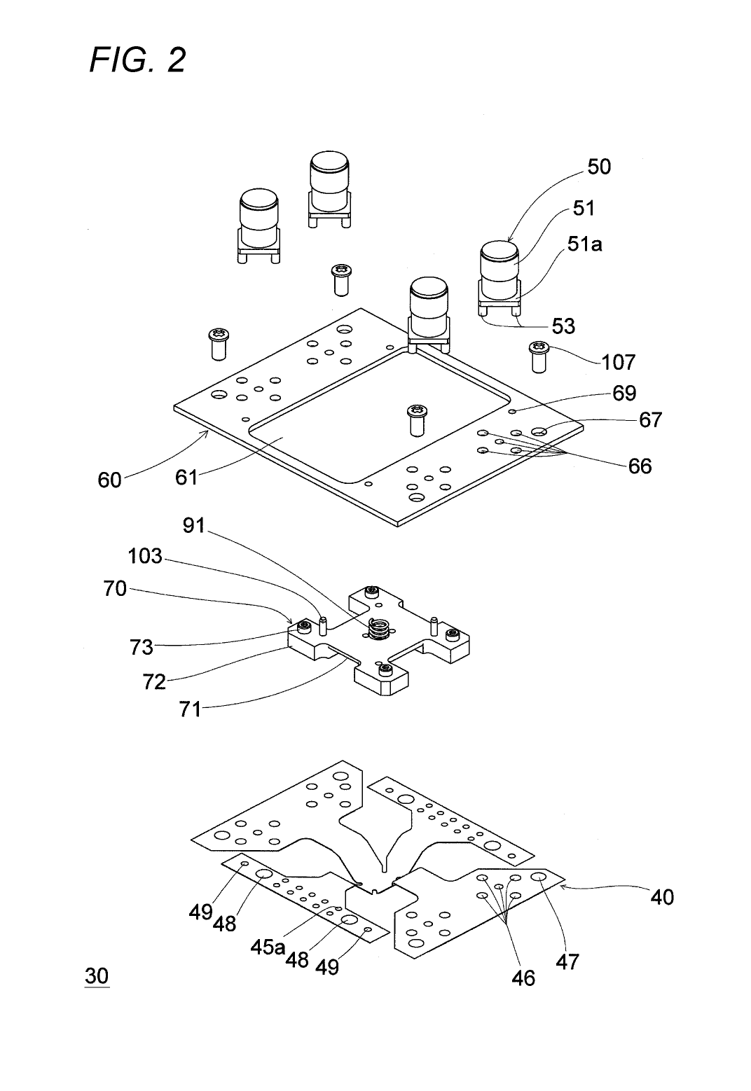

In addition to the above, the flexible board 40 is provided with connector leg passing holes 46, screw fastening holes 47, 48, and positioning holes 49, as shown in FIGS. 1 and 2. The connector leg passing holes 46 are provided for allowing the leg portions 52 for signals and leg portions 53 for ground of the coaxial connectors 50 to pass through. The screw fastening holes 47 are provided for allowing screws (fastening components) 107 for fixing the contact unit 30 to the main board 10 of the inspection jig 1 to pass through. It is to be noted that the screws 107 which are shown in FIGS. 1 and 2 need not necessarily be constituent elements of the contact unit 30. The screw fastening holes 48 are provided for allowing screws (fastening components) 108 for fixing the unit pressing member 90 of the inspection jig 1 which is shown in FIGS. 3 and 4 to the main board 10 to pass through. The screw fastening holes 48 are respectively provided at both sides of the through holes 45. The positioning holes 49 are provided for allowing positioning pins 109 (FIG. 4) for positioning the contact unit 30 with respect to the main board 10 to pass through. The positioning holes 49 are provided adjacent to the screw fastening holes 48. When the contact unit 30 is attached to the inspection jig 1, the flexible board 40 is not bonded to the below described main board 10 by soldering or so.

The four coaxial connectors 50 are directly and electrically connected to the flexible board 40, at such positions as to surround the contact region 41 of the flexible board 40, and coaxial cables extended from an inspection apparatus (a tester), which is not shown, can be detachably connected to the coaxial connectors 50. Each of the coaxial connectors 50 includes a body part 51, a piece of the leg portion 52 for signal, and the four leg portions 53 for ground. One end of the coaxial cable is connected to the inspection apparatus, and the other end of the coaxial cable is detachably connected (attached) to the body part 51. The body part 51 is positioned on the other face (an upper face) of the sub board 60. A flange part 51a of the body part 51 is fixed to a connector fixing land 62 (not shown) of the sub board 60 by soldering or so. The leg portion 52 for signal and the leg portions 53 for ground are extended from the body part 51, pass through connector leg passing holes 66 in the sub board 60 and the connector leg passing holes 46 in the flexible board 40, and then, directly and electrically connected to the face of the flexible board 40 at an opposite side to the sub board 60 by soldering or so. When the contact unit 30 is attached to the inspection jig 1, the coaxial connectors 50 are not bonded to the below described main board 10 by soldering or so.

The sub board 60 as a support member (a support board) is provided for the purpose of preventing a large load from being applied to a joint part (a soldered part) between the flexible board 40 and the coaxial connector 50, on occasion of attaching or detaching the coaxial cable to the coaxial connector 50. The sub board 60 is provided with a center through hole 61, the connector leg passing holes 66, screw fastening holes 67, and positioning holes 69. The center through hole 61 provides a space for disposing the block 70. The connector leg passing holes 66 are provided for the purpose of inserting the leg portions 52 for signal and the leg portions 53 for ground of the coaxial connectors 50. The screw fastening holes 67 are provided for the purpose of inserting the screws 107 for fixing the contact unit 30 to the main board 10 of the inspection jig 1. The positioning holes 69 are provided for the purpose of inserting the positioning pins 109 (FIG. 4) for positioning the contact unit 30 with respect to the main board 10.

The block 70 is urged downward by a spring 91, in a state incorporated in the inspection jig 1, thereby to hold the flexible board 40 in such a state that the contact region 41 is protruded downward from a lower face of the main board 10. The block 70 has four leg portions 72 around a center pyramid part 71 which is projected downward. Parallelism adjusting screws 73 are respectively attached to the leg portions 72 of the block 70. Tip ends of the parallelism adjusting screws 73 are in contact with base parts 22 for block of a retainer 20, which will be described below. Position of the block 70 which is urged by the spring 91 is determined in a vertical direction, when the tip ends of the parallelism adjusting screws 73 come into contact with the base part 22 for the block of the retainer 20. Two positioning pins 103 are held by the block 70 to be projected upward. The positioning pins 103 have a function of positioning the below described unit pressing member 90 with respect to the contact unit 30. Although the spring 91 is shown at an upper side than the block 70 in FIG. 2, it is to be noted that the spring 91 may be held by the unit pressing member 90 of the inspection jig 1 by holding or so, and need not be necessarily a constituent element of the contact unit 30. The block 70 has a flat face part 74 on a top of the pyramid part 71. The flat face part 74 is in contact with a back face of the contact region 41 of the flexible board. 40.

The inspection jig 1 is a probe card, for example, and used for inspecting electrical performance of a semiconductor integrated circuit in a state of a wafer. The inspection jig 1 includes the main board 10 formed of, for example, a glass epoxy board, the retainer 20 formed of metal such as stainless steel, and the above described contact unit 30, and the unit pressing member 90 formed of, for example, a resin molded body.

As shown in FIG. 4, the main board 10 is provided with a through hole 11 for contact, through holes 15, connector leg passing holes 16, and screw fastening holes 17, 18. The through hole 11 for contact is provided for the purpose of allowing the contact region 41 of the flexible board 40 to protrude downward. The through holes 15 are provided for establishing electrical connection with the through holes 45a of the flexible board 40. The connector leg passing holes 16 are provided for the purpose of avoiding the leg portions 52 for signal, and the leg portions 53 for ground of the coaxial connectors 50. The screw fastening holes 17 are provided for the purpose of passing the screws 107 for fixing the contact unit 30 to the main board 10. The screw fastening holes 18 are provided for the purpose of passing the screws 108 for fixing the unit pressing member 90 to the main board 10. Ground patterns which are not shown are provided on the upper face (the face opposed to the flexible board 40) of the main board 10 around the connector leg passing holes 16 and the screw fastening holes 17. By fastening with the screws 107, the ground patterns of the main board 10 and the ground patterns of the flexible board 40 come into face contact with each other. Because both of the ground patterns are extended around the screw fastening holes 17, 47, the ground patterns are firmly brought into face contact with each other, particularly in regions around the positions where they are fixed with the screws 107.

As shown in FIGS. 3 and 4, the retainer 20 is a thin sheet metal, for example, and has a function of restricting a downwardly protruding amount of the contact unit 30 from the main board 10. The retainer 20 is attached (fixed) to the lower face of the main board 10 with screws (fastening members) 106. The retainer 20 is provided with a through hole 21 for contact in a shape of a cross, and screw holes 27, 28. The base parts 22 for block (FIG. 4) are formed around the through hole 21 for contact. The through hole 21 for contact is provided for the purpose of allowing the contact region 41 of the flexible board 40 to protrude downward. The screw holes 27 are adapted to be engaged with the screws 107 for fixing the contact unit 30 to the main board 10 of the inspection jig 1. The screw holes 28 are adapted to be engaged with the screws 108 for fixing the unit pressing member 90 to the main board 10. The base parts 22 for block are respectively positioned below the leg portions 72 of the block 70, and bear (support) the tip ends of the parallelism adjusting screws 73 which are attached to the leg portions 72 and extended downward from the leg portions 72. Positioning pins 104 and 109 are provided on the retainer 20 and projected upward from the upper face of the main board 10. The positioning pins 104 have a function of positioning the unit pressing member 90 with respect to the main board 10. The positioning pins 109 have a function of positioning the contact unit 30 with respect to the main board 10. The main board 10 and the retainer 20 compose the main body of the inspection jig 1.

The unit pressing member 90 is a member for pressing the contact unit 30 from the above. As shown in FIG. 4, the unit pressing member 90 is provided with positioning holes 93, 94, connector body passing holes 95, and a recess 96 for spring (FIG. 3). The positioning holes 93 are provided for the purpose of passing the positioning pins 103 for positioning the unit pressing member 90 with respect to the contact unit 30. The positioning holes 94 are provided for the purpose of passing the positioning pins 104 for positioning the unit pressing member 90 with respect to the main board 10. The connector body passing holes 95 are provided for the purpose of protruding the body parts 51 of the coaxial connectors 50 upward. The recess 96 for spring is provided for the purpose of supporting one end of the spring 91 which is shown in FIG. 2. The spring 91 urges the block 70 downward (that is, urges the contact region 41 of the flexible board 40 downward), in a state where the unit pressing member 90 is fixed to the main board 10 with the screws 108, thereby to apply a contact force against the object to be inspected such as the wafer, to the contact region 41 of the flexible board 40. Two pieces of the elastic member 92 (FIG. 3) formed of silicone rubber or the like in a shape of a cord (a linear shape) are held on the lower face (the face opposed to the flexible board 40) of the unit pressing member 90. The elastic members 92 are provided at positions directly above the through holes 45a of the flexible board 40 and the through holes 15 of the main board 10, and press the through holes 45a of the flexible board 40 toward the through holes 15 of the main board 10, in a state where the unit pressing member 90 is fixed to the main board 10 with the screws 108. The screws 108 fix the unit pressing member 90 to the main board 10 at both sides of the elastic members 92 respectively, and hence, pressing effects by the elastic members 92 are enhanced. The through holes 15, 45a are brought into pressure contact with each other by the elastic members 92 thereby to be electrically connected.

A flow of an assembling work of the inspection jig 1 will be described below.

As a first step, the contact unit 30 is assembled in advance. Specifically, the following steps are carried out. The leg portions 52 for signal and the leg portions 53 for ground of the coaxial connectors 50 are passed through the connector leg passing holes 66 in the sub board 60, and the flange parts 51a of the coaxial connectors 50 are fixed to the connector fixing lands (not shown) on the upper face of the sub board 60 by soldering or so. Thereafter, while the leg portions 52 for signals and the leg portions 53 for ground of the coaxial connectors 50 are passed through the connector leg passing holes 46 in the flexible board 40, to which an electronic component (not shown) has been mounted and the block 70 has been bonded in advance, the flexible board 40 is set on the lower face (the face at an opposite side to the face where the body parts 51 of the coaxial connectors 50 are fixed) of the sub board 60. Then, the leg portions 52 for signal and the leg portions 53 for ground of the coaxial connectors 50 are connected directly and electrically to the lower face (the face at the opposite side to the sub board 60) of the flexible hoard 40 by soldering or so. It is also possible to fix the flange parts 51a of the coaxial connectors 50 to the upper face of the sub board 60, after the leg portions 52 for signal and the leg portions 53 for ground of the coaxial connectors 50 have been electrically connected to the lower face of the flexible board 40 in advance. The flexible board 40 is indirectly fixed to the sub board 60, because the leg portions 52 for signal and the leg portions 53 for ground of the coaxial connectors 50 are fixed to the sub board 60 by soldering. In this manner, the assembling work of the contact unit 30 is completed. It is to be noted that the block 70 may be passed through the center through hole 61 of the sub board 60, and fixed to the back face of the contact region 41 of the flexible board 40 by bonding, in a final step.

Then, the contact unit 30 is attached (fixed) to the main board 10 with the screws 107. Specifically, the four positioning pins 109 projected from the main board 10 are respectively passed through the positioning holes 49 in the flexible board 40 and the positioning holes 69 in the sub board 60. At the same time, the four screws 107 are respectively passed through the screw fastening holes 67 in the sub board 60, the screw fastening holes 47 in the flexible board 40, and the screw fastening holes 17 in the main board 10, and screwed into the screw holes 27 in the retainer 20 which has been fixed to the lower face of the main board 10 in advance. In this manner, the flexible board 40 is clamped between the main board 10 and the sub board 60.

Then, the unit pressing member 90 is fixed to the main board 10 with the screws 108. Specifically, the two positioning pins 103 which are projected upward from the block 70 and the two positioning pins 104 which are projected upward from the main board 10 are respectively passed through the positioning holes 93, 94 in the unit pressing member 90. At the same time, the four screws 108 are passed through the screw fastening holes in the unit pressing member 90, the screw fastening holes 48 in the flexible board 40 and the screw fastening holes 18 in the main board 10, and screwed into the screw holes 28 in the retainer 20. The parallelism of the contact region 41 of the flexible board 40 is adjusted by turning the parallelism adjusting screws 73, according to necessity. In this manner, the assembling work of the inspection jig 1 is completed. It is to be noted that the contact unit 30 can be detached from the main board 10 by conducting the assembling steps in a reverse order.

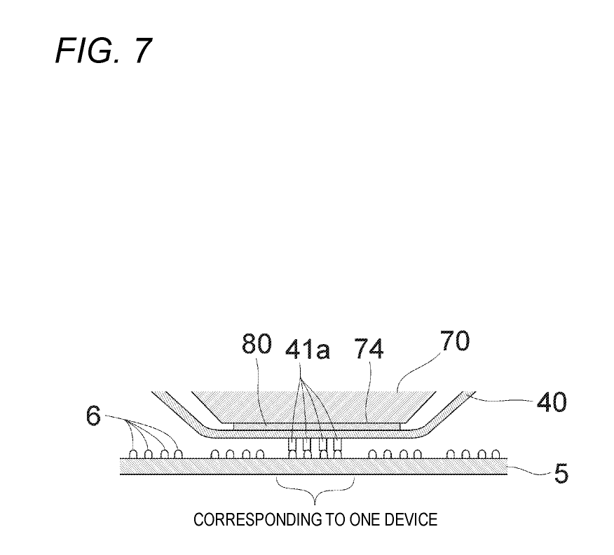

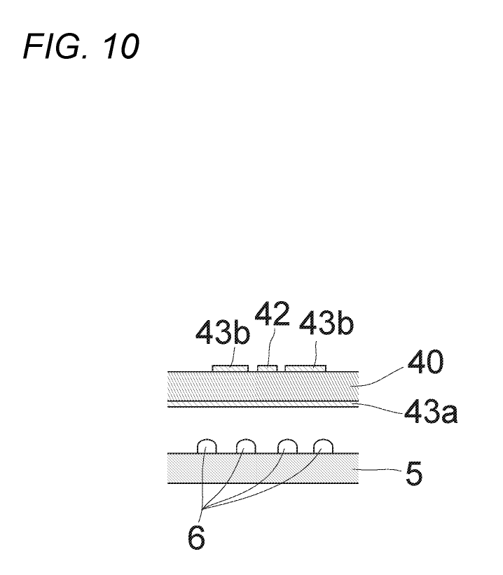

Referring to FIGS. 7 to 14, signal transmission on the flexible board 40 will be described below. In FIG. 7, the flat face part 74 of the block 70 and the flexible board 40 are bonded to each other with a bonding sheet 80. The respective bumps (the contact parts) 41a provided on the flexible board 40 and the electrodes 6 of the devices which are formed on the wafer 5 are in contact with each other.

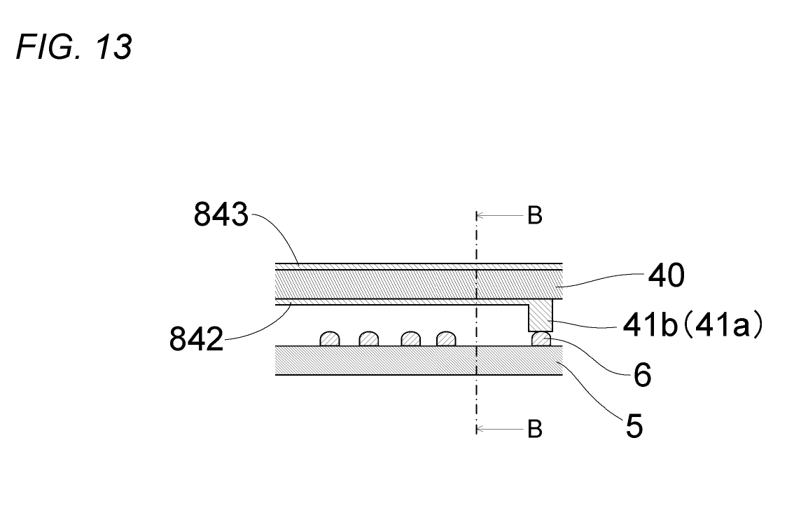

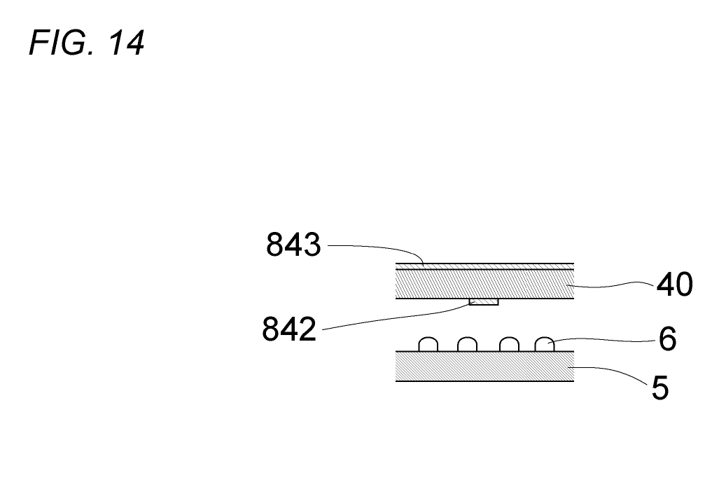

In case where the wafer 5 including a number of (a plurality of) devices is the object to be inspected, while the inspection is carried out as shown in FIG. 7, the lower face (the face opposed to the wafer 5) of the flexible board 40 is opposed to the electrode 6 of the device which is not being inspected (not during the inspection) but positioned adjacent to the device during the inspection, in proximity with each other. For this reason, as seen in comparative examples which are shown in FIGS. 13 and 14, in case where a signal pattern 842 for transmitting high-speed signals is led outward below the flexible board 40, and a ground pattern 843 is provided one the entire upper face of the flexible board 40, the signal pattern 842 is opposed to the device which is not being inspected but positioned adjacent to the device under inspection, in proximity with each other, by a unit of several ten μm, and causes inductive coupling and capacitive coupling between them. As the results, mismatch of impedance occurs, and inherent performance of the device cannot be accurately measured.

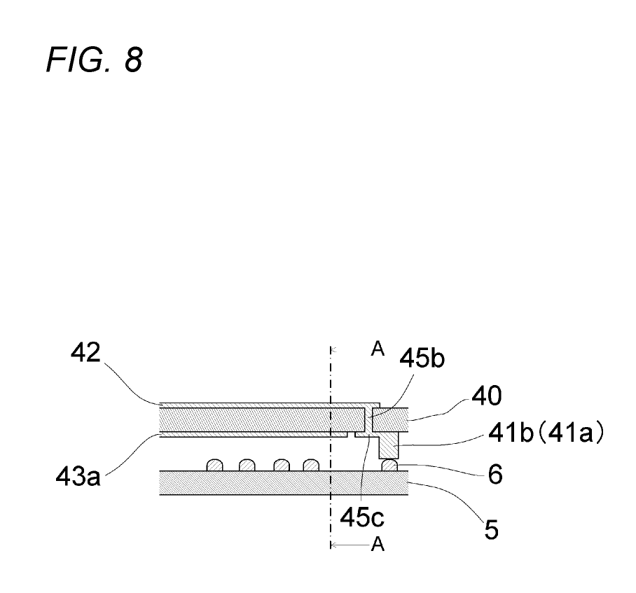

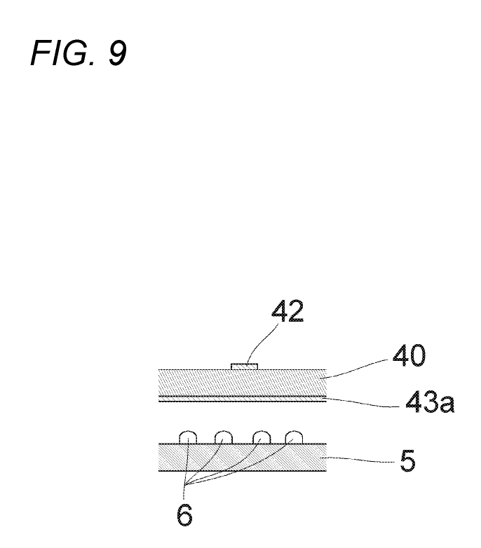

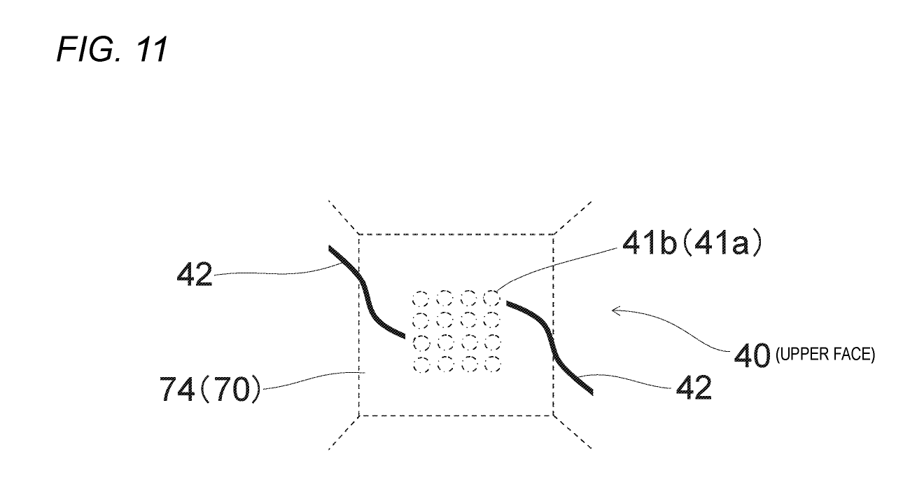

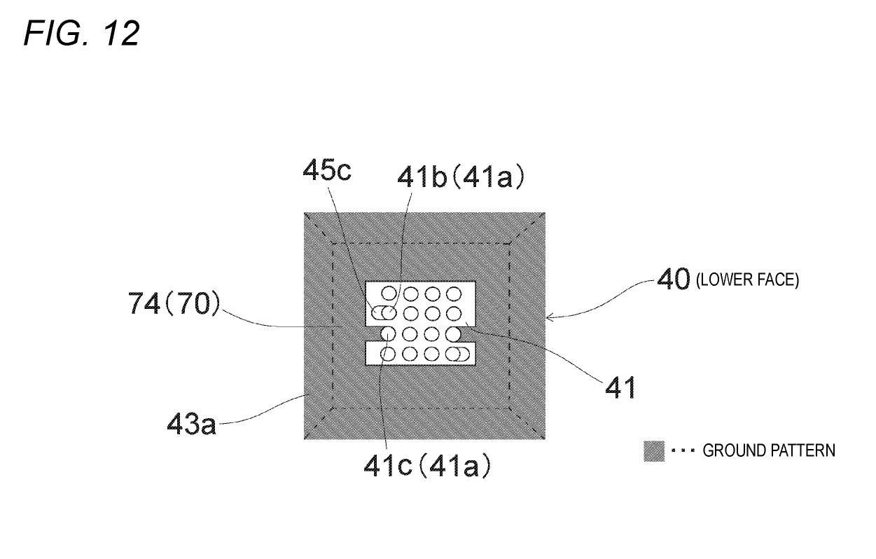

In view of the above, in this embodiment, the signal pattern 42 for transmitting the high-speed signals (signals in GHz band such as several GHz) is led outward on the upper face (the face at the opposite side to the wafer 5) of the flexible board 40, as shown in FIGS. 8 and 11, and a ground pattern 43a (corresponding to the first ground pattern in the claims) is extensively provided on the lower face of the flexible board 40 except the contact region 41 (the region where a plurality of the bumps 41a are formed and has a certain width with respect to ends of the respective bumps 41a), as shown in FIGS. 8 and 12. FIG. 9 shows an example where the signal pattern 42 forms a micro strip line together with the ground pattern 43a, while 10 shows an example where the signal pattern 42 forms a coplanar line together with ground patterns 43b (corresponding to the second ground pattern in the claims) which are respectively provided at both sides of the signal pattern 42 in proximity thereof. The ground patterns 43b are electrically connected to the ground pattern 43a by way of through holes which are not shown, near the through holes 45b, and also electrically connected to the leg portions 53 for ground of the coaxial connectors 50.

The signal pattern 42 is electrically connected to the bump 41b for high-speed signals by way of the through hole 45b as shown in FIG. 8. The through hole 45b is connected to an electrode 45c which is extended from the bump 41b for high-speed signals, and provided at a position close to the bump 41b for high-speed signals but not superposed on the bump 41b for high-speed signals, as seen in a direction perpendicular to the contact part forming region of the flexible board 40. Moreover, the signal pattern 42 is guided to the lower face side of the connector leg passing holes 46 (See FIGS. 1 and so on) of the flexible board 40 through which the leg portions 52 for signals of the coaxial connectors 50 are passed, and electrically connected to the leg portions 52 for signals by soldering or so. The ground pattern 43a is electrically connected to the bump 41c for ground out of the bumps 41a, as shown in FIG. 12, and at the same time, electrically connected to the leg portions 52 for signals of the coaxial connectors 50 by soldering or so. Although not shown in the drawings, an electrically conductive pattern (a pattern for power supply or a pattern for low-speed signals) which is electrically connected to the respective bumps 41a except the bumps 41b for high-speed signals and the bump 41c for ground, by way of through holes, is provided on the upper face of the flexible board 40. This electrically conductive pattern is electrically connected to either of the through holes 45a which are provided in the end parts of the cross part of the flexible board 40.

According to this embodiment, the signal pattern 42 for transmitting high-speed signals is led outward on the upper face of the flexible board 40, and the ground pattern 43a is extensively provided on the lower face of the flexible board 40 except the contact region 41. Therefore, as compared with the structures in the comparative examples in FIGS. 13 and 14, it is possible to make a distance between the signal pattern 42 and the electrodes 6 of the device larger by a thickness of the flexible board 40. At the same time, the ground pattern 43a functions as a shield by covering the signal pattern 42 with the flexible board 40 interposed between the ground pattern 43a and the signal pattern 42 (because the ground pattern 43a is interposed between the signal pattern 42 and the electrodes 6 of the adjacent device which is not being inspected). As the results, it is possible to prevent occurrence of the capacitive coupling or inductive coupling between the signal pattern 42 and the adjacent device which is not being inspected, and it is possible to measure the inherent performance of the device with high accuracy.

### Embodiment 2

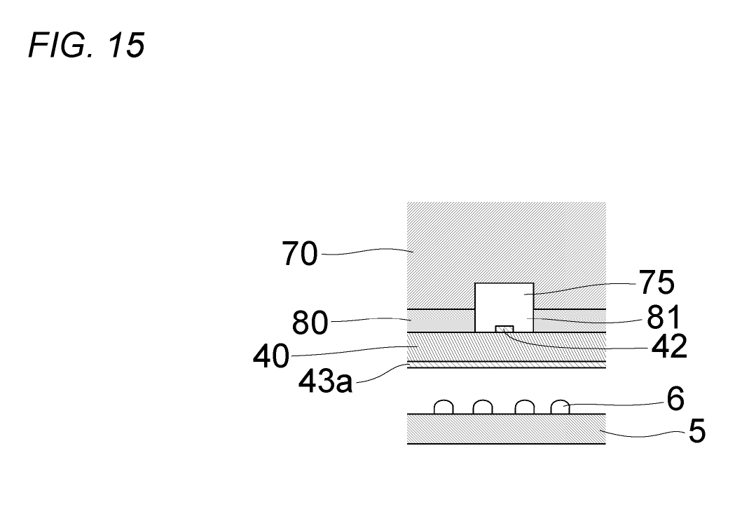

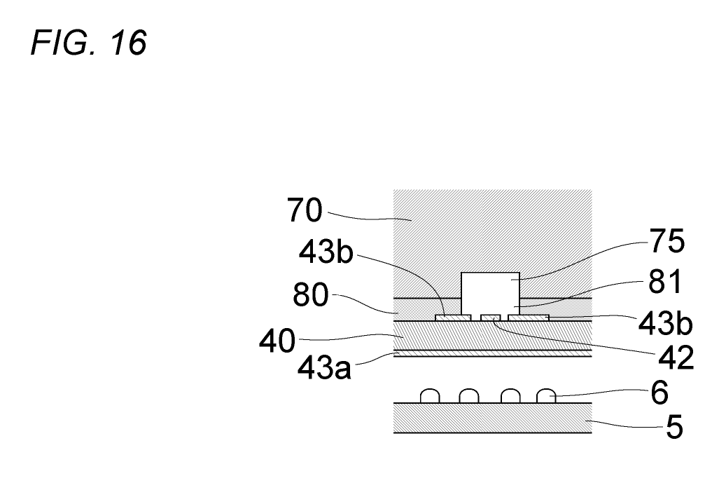

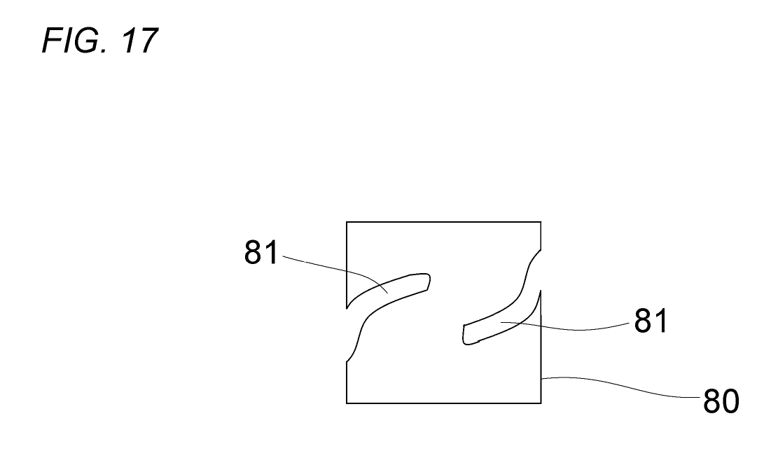

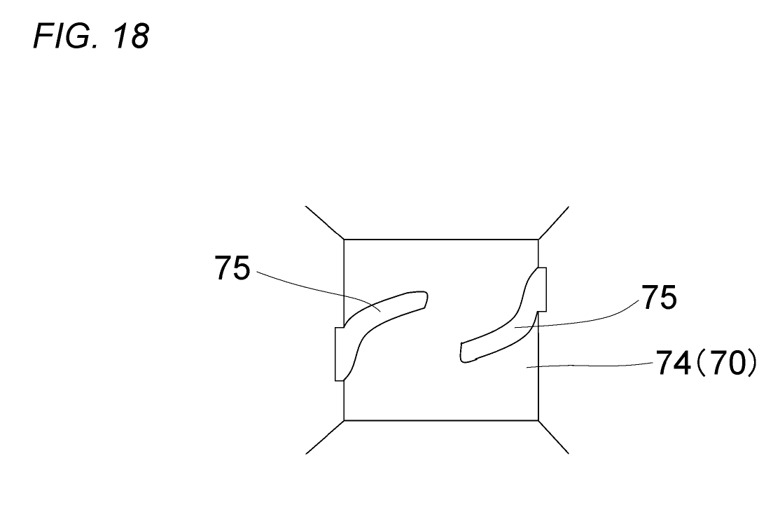

Referring to FIGS. 15 to 18, Embodiment 2 of the invention will be described. Although the signal pattern 42 is in contact with the bonding sheet 80 in Embodiment 1, it is so constructed in this embodiment that the bonding sheet 80 is provided with cutout parts 81 in a region opposed to the signal pattern 42, as shown in FIG. 17. The block 70 is provided with concave parts (concave grooves) 75 in a region opposed to the signal pattern 42, as shown in FIG. 18, so that the signal pattern 42 may be brought into contact with an air in a region opposed to the concave parts 75. Widths and heights of the concave parts 75 and the cutout parts 81, that is, a width and a height of an air layer above the signal pattern 42, are preferably more than three times as large as the width of the signal pattern 42. Other features of the present embodiment are substantially the same as those in Embodiment 1. According to this embodiment, because the signal pattern 42 is in contact with the air at the position opposed to the concave parts 75, it is possible to restrain deterioration of the high frequency performance, as compared with the case where the signal pattern 42 is in contact with the bonding sheet 80 which is an inductive body having a larger inductivity than the air.

The invention has been heretofore described referring to the embodiments as examples. However, it is to be understood by those skilled in the art that various modifications can be added to the constituent elements and the treating processes in the embodiments within a scope described in the claims. The modifications will be briefly described below.

The ground pattern 43a need not be provided on the entire lower face of the flexible board 40, provided that it covers the signal pattern 42 with the flexible board 40 interposed between the ground pattern 43a and the signal pattern 42. For example, the ground pattern 43a may be such a pattern as extended along the signal pattern 42. In this case, the width of the Ground pattern 43a is preferably more than three times as large as the width of the signal pattern 42. The through holes 45b may be provided at the position superposed on the bumps 41b for high-speed signals, as seen in a direction perpendicular to the contact part forming region of the flexible board 40.

The inspection jig may be so constructed that the coaxial connectors 50 and the flexible board 40 are directly fixed to the main board 10 by soldering or so, without providing the sub board 60. Besides, parameters such as the number of the coaxial connectors 50, the number of the through holes, the number of the screws for fixing the respective parts, the number of the positioning pins are not limited to the specific numbers which are described as examples in the embodiments, but can be optionally determined according to required performances and convenience in designing.

According to an aspect of the invention, a contact unit and an inspection jig are capable of measuring performance of a device with high accuracy.

What is claimed is:

1. A contact unit which is to be detachably attached to a body of an inspection jig, the contact unit comprising:
a flexible board which is provided with a contact part to be in contact with an object to be inspected, on one face thereof;
a support member which is configured to support the flexible board; and
a block which is provided on a side of the other face of the flexible board, wherein
a first ground pattern is provided on the one face of the flexible board,
a signal pattern is provided on the other face of the flexible board,
a through hole for electrically connecting the signal pattern to the contact part is formed in the flexible board, and
the first ground pattern covers the signal pattern with the flexible board interposed between the first ground pattern and the signal pattern.

2. An inspection jig comprising:
a flexible board which is provided with a contact part to be in contact with an object to be inspected, on one face thereof;
a support member which is configured to support the flexible board; and
a block which is provided on a side of the other face of the flexible board, wherein
a first ground pattern is provided on the one face of the flexible board,
a signal pattern is provided on the other face of the flexible board,
a through hole for electrically connecting the signal pattern to the contact part is formed in the flexible board, and
the first ground pattern covers the signal pattern with the flexible board interposed between the first ground pattern and the signal pattern.

3. The inspection jig according to claim 2, wherein
the block has a concave part in a region opposed to the signal pattern, and the signal pattern is in contact with an air, in a region opposed to the concave part.

4. The inspection jig according to claim 2, wherein
the first ground pattern is extensively provided on the one face of the flexible board, except a region where the contact part is provided.

5. The inspection jig according claim 2, wherein
second ground patterns are provided at both sides of the signal pattern thereby to form a coplanar line.

6. The inspection jig according to claim 2, wherein
the signal pattern and the first ground pattern form a micro strip line.

7. The inspection jig according to claim 2, wherein
the through hole is formed in the flexible board at a position which is close to the contact part, but not superposed on the contact part, as seen in a direction perpendicular to a region where the contact part is provided.

8. The inspection jig according to claim 2, wherein
the signal pattern is a pattern for transmitting high frequency signals in a GHz band.

9. The inspection jig according to claim 2, further comprising an urging unit which is configured to urge the block toward the object to be inspected.
